(19) United States
(12) Patent Application Publication
(10) Pub. No.: US 2004/0248403 A1
(43) Pub. Date: Dec. 9, 2004

(54) Method for forming electroless metal low resistivity interconnects

(76) Inventors: Valery M. Dubin, Portland, OR (US); Peter K. Moon, Portland, OR (US)

Correspondence Address: Edwin H. Taylor, Blakely, Sokoloff, Taylor & Zafman LLP, Seventh Floor, 12400 Wilshire Boulevard, Los Angeles, CA, 90025-1030, US

(21) Appl. No.: 10/458,042

(22) Filed: Jun. 9, 2003

(51) Int. Cl. H01L 21/4763

(52) U.S. Cl. 438/637; 438/678; 438/687

(57) ABSTRACT

A process for forming electroless metal conductors in an integrated circuit as part of, for example, a damascene or dual damascene process without the use of a seed layer, is described. A catalyst is used to cause the via openings and trenches to be filled from the bottom up, thereby minimizing voids.

### FIELD OF THE INVENTION

The invention relates to the field of interconnect structures in an integrated circuit such as those formed with a damascene process.

### BACKGROUND OF THE INVENTION

Many integrated circuits contain multi-layer electrical interconnect structures to provide electrical signals to logical elements such as transistors located on a semiconductor substrate. The interconnect structures often contain interconnect lines which are spaced apart in a nearly coplanar arrangement within a dielectric material that insulates the lines from one another. Selected connections between interconnect lines on different levels are made by vias formed through the insulating material.

The interconnect lines are often made of highly conductive metals or alloys. Copper has become a widely used material due, in part, to its low electrical resistance compared to other metals. Typically, the copper is electroplated in the damascene process. A barrier layer is used to prevent diffusion of the copper into dielectric layers. Chemical mechanical polishing (CMP) removes the copper and barrier layers from the upper surface of the dielectric, leaving the barrier layer and copper inlaid within the trenches and vias. A cladding metal, in some cases, is selectively deposited over the copper to seal it and to provide an etchant stop for additional interconnect layers.

Problems associated with this process are described later in conjunction with FIG. 1.

### BRIEF DESCRIPTION OF THE DRAWINGS

FIG. 1 is a cross-sectional elevation view of a partially fabricated interconnect layer in an integrated circuit as done in the prior art.

FIG. 2 is a cross-sectional elevation view of an interlayer dielectric (ILD) formed above an underlying interconnect layer with trenches and a via opening etched in the ILD. FIG. 2 also illustrates a floating catalyst formed on a barrier layer lining the ILD.

FIG. 3A is an enlarged view of the via opening of FIG. 2.

FIG. 3B illustrates the via opening of FIG. 2 as a metal is formed in the opening by an electroless process.

FIG. 3C illustrates the via of FIG. 2 as the metal is continued to be formed in the via opening. FIG. 3C is used to illustrate the filling of the via opening from the bottom up.

FIG. 3D illustrates the via opening of FIG. 3C after the via is filled.

FIG. 4 illustrates the structure of FIG. 2 after an electroless deposition of metal conductors and vias.

FIG. 5 illustrates the structure of FIG. 4 after a planarization step and the formation of cladding.

FIG. 6 is a diagram used to illustrate the epitaxial-like formation of copper on a smooth catalytic metal.

FIG. 7 illustrates the epitaxial-like formation of a metal layer on an ILD or barrier layer using a self-assembled solution.

### DETAILED DESCRIPTION

A method of fabricating interconnects in an integrated circuit is disclosed using an electroless process. In the following description, numerous specific details are set forth, such as specific metals, catalysts and other materials, in order to provide a thorough understanding of the present invention. It will be apparent to one skilled in the art that the present invention may be practiced without these specific details. In other instances, well-known processes have not been set forth in detail, in order not to unnecessarily obscure the invention.

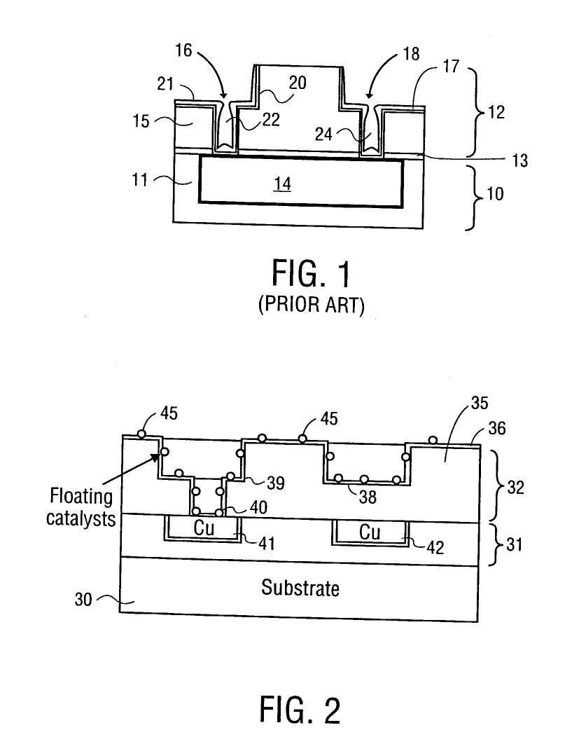

Referring first to FIG. 1, a problem associated with damascene processing (including dual damascene processing) as well as with other gap filling processes is illustrated. This problem is particularly troublesome as the critical dimension in a process reaches sub-0.05 μm.

In the cross-sectional view of FIG. 1, an interconnect layer 10 is illustrated having inlaid therein a conductor 14. Overlying layer 10 is a partially fabricated interconnect layer 12. An etchant stop layer 13 is disposed between the dielectric layers 11 and 15, as is often used in damascene processing. Two via openings, 22 and 24, are shown in FIG. 1, etched into the dielectric layer 15. These via openings terminate in partially shown trenches. A barrier layer 17, lines the trenches and via openings to prevent the subsequently deposited metal, for instance copper, for diffusing into the dielectric layer.

A seed layer 21 is formed on the barrier layer to provide a more conductive surface for the subsequent electroplating of for example, copper conductors and vias. The seed layer typically has poor sidewall coverage in the via opening. Moreover, the seed layer has relatively large overhangs, which narrow the via opening, as shown by the narrowed openings 16 and 18. These relatively large overhangs along with the poor sidewall coverage can result in voids in the electroplated metal. Where critical dimensions are approximately 0.05 μm, the narrowing of the openings shown at 16 and 18 of FIG. 1 become particularly critical, and make the electroplating of copper, for instance, problematic.

To solve this problem, the present invention uses the electroless deposition of a metal without a seed layer and uses a floating catalyst to cause the metal to be deposited in, for instance, a via opening from the bottom up.

Electroless metal plating is an autocatalytic (non-electrolytic) method of deposition from solution. The electrons required for the metal reduction are supplied by the simultaneous oxidation of a reducing agent on the catalytic surface and reduction of metal ions. Plating is initiated on a catalyzed surface and is sustained by the catalytic nature of the plated metal surface itself.

An electroless plating solution generally includes water, a water soluble compound containing the metal (in ion form) to be deposited onto the target (surface), a complexing agent that prevents chemical reduction of the metal ions in solution while permitting selective chemical reduction on a surface of the target, and a chemical reducing agent for the metal ions. Additionally, the plating solution may also include a buffer for controlling pH and various optional additives, such as solution stablizers and surfactants. It is, of course, understood that the composition of a plating solution will vary depending on the desired outcome.

For example, a simple Cu salt (1-10 g/l) such as copper sulfate, copper chloride or copper nitrate may be used as the source of copper. Formaldehyde, hypophosphite, and glyoxylic acid can be used as reducing agents (2-15 g/l) for an electroless deposition of Cu.

For discussion of the electroless plating of metals in semiconductor fabrication, see “Electroless Method of Seed Layer Deposition, Repair and Fabrication of Cu Interconnects,” Ser. No. 09/728,683, filed Nov. 29, 2000, and “Apparatus and Method for Electroless Spray Deposition,” Ser. No. 10/046,218, filed Jan. 16, 2002.

The direct electroless plating of copper on relatively high resistant barriers such as TaN, often results in poor uniformity of copper coverage over the wafer. The etching of native metal oxides using, for instance, an acidic solution prior to the plating often results in poor copper/barrier adhesion. In general, the direct electroless plating on these barriers results in voids forming because of the general conformal deposition of the electroless plating.

Referring now to FIG. 2, processing in accordance with an embodiment of the current invention is shown. A substrate 30, illustrated in cross-sectional, elevation view may be an ordinary monocrystalline silicon substrate upon which transistors are fabricated as is well known. A first interconnect layer 31 is shown with two conductors 41 and 42. This first layer 31 may be fabricated in the same manner as is described below for layer 32.

For the fabrication of the second interconnect layer 32, interlayer dielectric (ILD) 35 is first formed on the layer 31 in the same manner as a dielectric layer is formed in a damascene process. For instance, chemical vapor deposition (CVD) may be used to form a silicon dioxide layer. Then, openings for vias and conductors are etched into the layer 35. For instance, the via opening 40 and the trenches 38 and 39 are etched.

In one embodiment, it is preferred that the walls of the via openings and trenches are smooth as is more often the case where the dielectric is relatively dense. If a porous dielectric is used, it may be desirable to seal the sidewalls of the trenches and via openings to fill pores in a porous dielectric. Any one of numerous, well-known dielectrics may be used for the ILD 35.

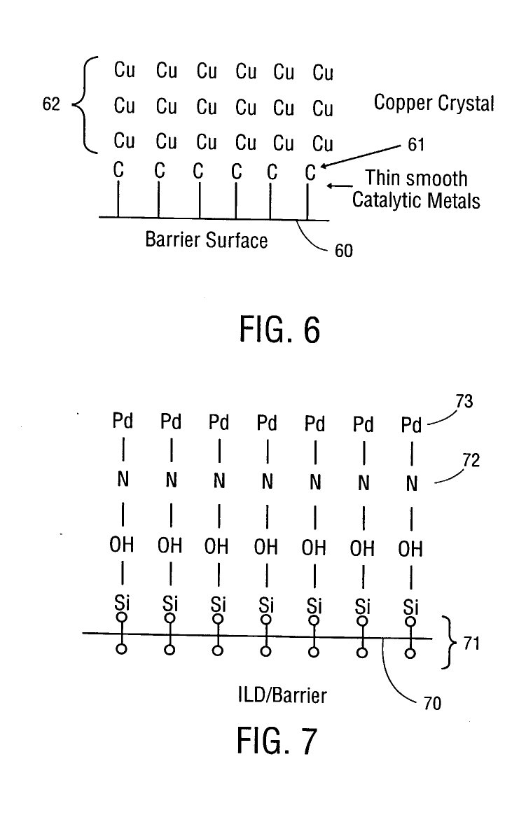

Next, a barrier layer 36 is formed as is typically done in a damascene process to prevent the diffusion of a metal such as copper into the dielectric. A catalytic metal may be used such as a Au, Pd, Pt, Ru or Rh. These catalytic metals are preferred in one embodiment because they do not contain oxide on their surface or surface oxide is reduced during the electroless deposition of, for instance, copper. This allows the copper to form in a more ordered structure resembling an epitaxial-like growth such as shown in FIG. 6. Note in FIG. 6, the thin smooth catalytic metal 61 at surface 60 provides an ordered transition into the copper 62. This type of formation eliminates surface scattering which further reduces line resistance.

The barrier layer may be formed with ordinary steps which may include in-situ degas, pre-cleaning and deposition using, for instance, physical vapor deposition (PVD). In one embodiment it is preferred that the barrier layer be relatively thin, that is, in a range from a mono-layer to 200 Å thick.

Where a non-catalytic barrier is used, such as Ta, Ti, W and alloys containing these elements along with N or Si, an interface is needed between the barrier and a catalytic surface. This is shown in FIG. 7 with a surface 70 which represents a non-catalytic surface. The surface 70 could also be an ILD. The processing described for creating this interface may also be used for smoothing an ILD.

A layer of azole silane with Pd materials supplied by Nikko Materials is used on the surface 70. This forms a smoothing bond with the ILD or barrier layer 70 as shown by 71. Pd catalyst is applied to bond with the N. This is shown by Pd 73 bonding to the N 72 in FIG. 7. The result is a ordered structure somewhat epitaxial-like which results in a Pd catalytic metal surface more suitable for the electroless plating of the vias and conductors.

The barrier layer ideally should have low resistivity (<100 μohm cm), and thus, metals such as alpha-Ta, W, Ru, Rh, Co, and Nickel may be used. Moreover, as mentioned, it should be thin (e.g., 200 Å or less) and smooth.

After the barrier layer has been formed, the electroless forming of the copper (or other low resistance electroless metals such as Ag, Au, etc.) may occur. Note this is done without a seed layer.

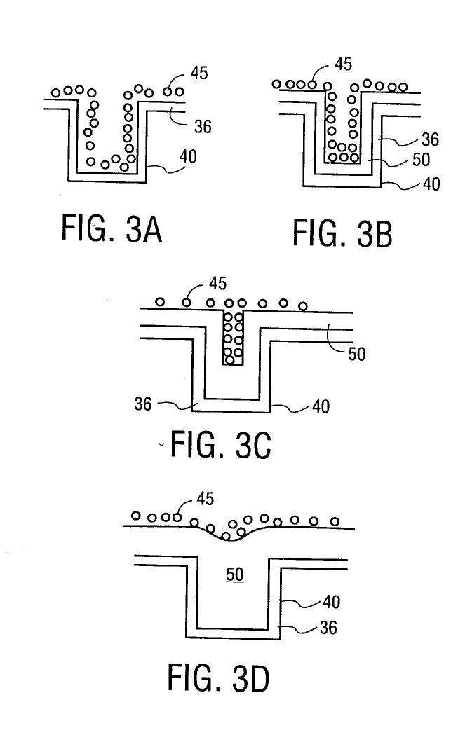

A catalyst which floats is used to cause the copper to fill the vias and trenches from their bottom upwards. The catalyst accelerates the plating and as will be discussed, assuring that the narrow gaps of the via openings are filled. This catalyst may be a metal containing compound such as OsO₄, MoO₄ or tungstate. Iodidate organic compounds, a binary compound of iodine with electropositive atoms, may also be used. The catalyst may be compounds containing AgS, S and N such as mercaptopyridine or mercaptobenzothiazol. The catalyst in liquid form may be placed onto the barrier surface, for instance, by dipping, spin-on or spraying. Alternatively, the catalyst can be carried in the electroless plating solution. The catalyst is represented by the liquid 45 shown in FIGS. 2 and 3.

Following the application of the catalyst, the electroless plating of the low-resistance conductor such as copper occurs. As is typical in a damascene process, the vias, trenches and exposed surfaces of the ILD, all of which are covered by the barrier, receive the copper or other conductive metal.

Importantly, with the present invention, and because of the floating catalyst 45, the openings such as the vias are filled from the bottom up with the metal and not just in an ordinary conformal manner. As discussed above, the conformal deposition can result in voids forming.

In FIG. 3A an enlarged view of the via opening 40 is shown along with the barrier layer 36 and the floating catalyst 45. Assume for purposes of discussion that the electroless plating solution is also present and that the plating of, for instance, copper is occurring onto the barrier layer 36. As the deposition of the metal on layer 36 occurs, as shown by metal 50 in FIG. 3B, the density of the catalyst increases, particularly in the bottom of the via opening. The increased density of the catalyst causes the metal to be more quickly deposited. As this deposition in the bottom of the via opening occurs, the catalyst continues to float upwards as shown in FIG. 3C, causing the formation of the electrolessly formed metal to fill the opening from the bottom up. As shown in FIG. 3D the metal 50 has filled the via opening 40 and is beginning to fill the trench. This bottom up filling of, for instance, copper provides a smooth, well ordered, conductive layer such as shown in FIG. 6.

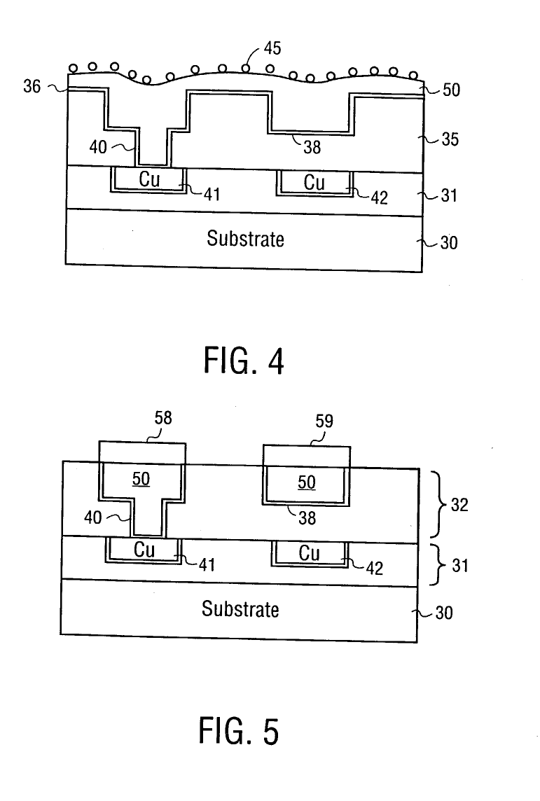

The electrode deposition in a damascene process continues until the trenches are filled. The resultant structure is shown in FIG. 4.

By way of example, electroless copper deposition can be done on a Ru barrier layer of 100 Å with good adhesion from a solution containing 5 g/l CuSO₄5H₂O, 16 g/l EDTA and 10 g/l gloxylic acid at a pH of 12.5 and a temperature of 65°-70° C.

Following the formation of the electroless metal, chemical mechanical polishing (CMP) or other etching may be used to planarize the surface of the wafer so as to expose the ILD between the inlaid conductors. This is the typical planarization that occurs in a damascene process.

Following the polishing step, a cladding layer may be formed over the conductors from a low conductivity material such as Co, W, Ta, Ti, Pd or their alloys containing N, B, P, Si or C. The full encapsulation of the conductors as known in the prior art, not only serves to prevent the metal from diffusing into the dielectric, but also acts as an etchant stop during the formation of overlying via openings. Known self-aligning processes may be used to form this cladding layer.

The resultant structure at this point of the processing is shown in FIG. 5 with the metal cladding members 58 and 59 covering the conductors.

The process described above may be repeated for each of the interconnect layers in an integrated circuit.

Thus, an electroless process for forming vias and conductors for an interconnect layer has been described where openings are filled from the bottom up. The process does not require a seed layer and consequently, the narrowing of a via opening that occurs because of seed layer overhangs is avoided.

What is claimed is:

1. A method for fabricating a conductor in an opening comprising:
forming a barrier layer in the opening; and
electrolessly filling the opening with a metal in the presence of a floating catalyst which causes the metal to form from a bottom of the opening to the top of the opening.

2. The method defined by claim 1, wherein the catalyst is applied to the barrier layer prior to the filling of the opening with a metal.

3. The method defined by claim 1, wherein the catalyst is contained within a solution used for the electroless plating of the opening with the metal.

4. The method defined by claim 1, wherein the metal is copper.

5. The method defined by claim 1, wherein the barrier layer is selected from the group of Au, Pd, Cu, Pt, Ru and Rh.

6. The method defined by claim 5, wherein the barrier layer is approximately 200 Å thick or less.

7. The method defined by claim 1, wherein the catalyst is selected from the group of OsO₄, MoO₄ and tungstate.

8. The method defined by claim 1, wherein the catalyst comprises an iodide organic compound.

9. The method defined by claim 1, wherein the catalyst includes sulfur.

10. The method defined by claim 1, wherein the catalyst includes nitrogen.

11. The method defined by claim 10, wherein the nitrogen is from mercaptopyridine or mercaptobenzothiazol.

12. The method defined by claim 1, including the step of planarizing the metal such that it remains in only the opening.

13. The method defined by claim 12, including the step of forming a cladding layer over the metal remaining in the opening.

14. The method defined by claim 13, wherein the cladding material is selected from the group of Co, W, Ta, Ti, Pd.

15. A method for fabricating an interconnect layer in an integrated circuit comprising:
forming an interlayer dielectric (ILD);
forming trenches and vias in the ILD;
depositing a barrier layer that lines at least the trenches and vias; and
electrolessly filling the trenches and vias with a metal in the presence of a floating catalyst which accelerates the metal formation.

16. The method defined by claim 14, wherein the catalyst is applied to the barrier layer prior to the filling of the opening with a metal.

17. The method defined by claim 14, wherein the catalyst is contained within a solution used for the electroless filling of the opening with the metal.

18. The method defined by claim 14, wherein the metal is copper.

19. The method defined by claim 14, wherein the metal is selected from the group of Au, Ag and Cu.

20. The method defined by claim 15, wherein the barrier layer is selected from the group of Au, Pd, Cu, Pt, Ru and Rh.

21. The method defined by claim 20, wherein the barrier layer is approximately 200 Å thick or less.

22. The method defined by claim 15, wherein the catalyst is selected from the group of OsO₄, MoO₄ and tungstate.

23. The method defined by claim 15, wherein the catalyst comprises an iodide organic compound.

24. The method defined by claim 15, wherein the catalyst includes sulfur.

25. The method defined by claim 15, wherein the catalyst includes nitrogen.

26. The method defined by claim 25, wherein the nitrogen is from mercaptopyridine or mercaptobenzothiazol.

27. The method defined by claim 15, including the step of planarizing the metal such that it is removed from a surface of the ILD lying between the filled trenches.

28. The method defined by claim 27, including the step of forming a cladding layer over the metal filling the trenches.

29. The method defined by claim 28, wherein the cladding material is selected from the group of Co, W, Ta, Ti, Pd.
